(19) United States
(12) Patent Application Publication
(10) Pub. No.: US 2007/0030914 A1
(43) Pub. Date: Feb. 8, 2007

(54) Method and system for channel estimation and interference cancellation in an orthogonal frequency division multiple access network

(75) Inventors: Yinong Ding, Plano, TX (US); Cornelius van Rensburg, Dallas, TX (US); Farooq Khan, Allen, TX (US)

Correspondence Address: DOCKET CLERK, P.O. DRAWER 800889, DALLAS, TX, 75380, US

(73) Assignee: SAMSUNG ELECTRONICS Co., LTD., Suwon-city (KR)

(21) Appl. No.: 11/483,974

(22) Filed: Jul. 10, 2006

Related U.S. Application Data
(60) Provisional application No. 60/704,642, filed on Aug. 2, 2005.

(51) Int. Cl. H04K 1/10; H03D 1/04; H04L 27/06

(52) U.S. Cl. 375/260; 375/346; 375/340

(57) ABSTRACT

A method of channel estimation and interference cancellation in an Orthogonal Frequency Division Multiple Access network is provided. The method includes determining an estimate of a transmitted signal based on an initial channel estimate and a received signal. An extracted transmitted signal is generated based on the estimate of the transmitted signal using a data integrity checking method. A subsequent channel estimate is generated based on the received signal and the extracted transmitted signal. If a subsequent iteration criterion is met, a subsequent estimate of the transmitted signal is determined based on the subsequent channel estimate and the received signal. A subsequent extracted transmitted signal is generated based on the subsequent estimate of the transmitted signal using a data integrity checking method. An additional subsequent channel estimate is generated based on the received signal and the subsequent extracted transmitted signal.

### CROSS-REFERENCE TO RELATED APPLICATION AND CLAIM OF PRIORITY

This application is related to U.S. Provisional Patent No. 60/704,642, filed Aug. 2, 2005, entitled IMPROVED CHANNEL ESTIMATION VIA ITERATIVE DECISION FEEDBACK AND INTEREFERENCE CANCELLATION (VIDIC)”. U.S. Provisional Patent No. 60/704,642 is assigned to the assignee of this application and is incorporated by reference as if fully set forth herein. This application claims priority under 35 U.S.C. §119(e) to U.S. Provisional Patent No. 60/704,642.

### TECHNICAL FIELD OF THE INVENTION

The present disclosure relates generally to wireless communications and, more specifically, to a method and system for channel estimation and interference cancellation in an orthogonal Frequency Division Multiple Access (OFDMA) network.

### BACKGROUND OF THE INVENTION

In OFDMA networks, channel estimation techniques typically involve relatively complicated procedures. In addition, initial channel estimates may be inaccurate to such an extent that the estimation diverges from the optimal value when decision feedback-based approaches are implemented. Because of these problems with conventional channel estimation techniques, existing decision feedback-based approaches may not yield reliable results in low signal-to-noise ratio and/or high bit error rate scenarios. Therefore, there is a need in the art for an improved channel estimation technique in OFDMA networks.

### SUMMARY OF THE INVENTION

A method for channel estimation and interference cancellation in an Orthogonal Frequency Division Multiple Access (OFDMA) network is provided. According to an advantageous embodiment of the present disclosure, the method includes determining an estimate of a transmitted signal based on an initial channel estimate and a received signal. An extracted transmitted signal is generated based on the estimate of the transmitted signal using a data integrity checking method. A subsequent channel estimate is generated based on the received signal and the extracted transmitted signal.

According to another embodiment of the present disclosure, a wireless receiver, e.g., user equipment (UE), capable of providing channel estimation and interference cancellation in an OFDMA network is provided that includes an initial channel estimator and an iterative module. The initial channel estimator is operable to generate an initial channel estimate. The iterative module is operable to determine an estimate of a transmitted signal based on an initial channel estimate and a received signal, to generate an extracted transmitted signal based on the estimate of the transmitted signal using a data integrity checking method, to generate a subsequent channel estimate based on the received signal and the extracted transmitted signal, and to determine whether a subsequent iteration criterion has been met.

According to yet another embodiment of the present disclosure, a wireless receiver, e.g., user equipment (UE), capable of providing channel estimation and interference cancellation in an OFDMA network is provided that includes an iterative module. The iterative module includes a transmitted signal extractor, a channel estimator and a subsequent loop initiator. The transmitted signal extractor is operable to generate an extracted transmitted signal based on an initial channel estimate, a received signal, and a data integrity checking method. The channel estimator is operable to generate a subsequent channel estimate based on the received signal and the extracted transmitted signal. The subsequent loop initiator is operable to determine whether a subsequent iteration criterion has been met.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the term “each” means every one of at least a subset of the identified items; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most, instances such definitions apply to prior, as well as future, uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an Orthogonal Frequency Division Multiple Access (OFDMA) wireless network that is capable of providing channel estimation and interference cancellation according to an embodiment of the present disclosure;

FIG. 2 illustrates a wireless receiver that is capable of channel estimation and interference cancellation according to an embodiment of the present disclosure;

FIG. 3 illustrates details of the iterative module of the wireless receiver of FIG. 2 according to an embodiment of the present disclosure;

FIG. 4 is a flow diagram illustrating a method for channel estimation and interference cancellation in the wireless receiver of FIG. 2 according to an embodiment of the present disclosure;

FIG. 5 illustrates details of the wireless receiver of FIG. 2 according to an embodiment of the present disclosure;

FIG. 6 illustrates an implementation of a portion of the wireless receiver of FIG. 2 in a 1×2 SIMO system according to an embodiment of the present disclosure; and

FIG. 7 illustrates an implementation of a portion of the wireless receiver of FIG. 2 in a 4×4 MIMO system according to an embodiment of the present disclosure.

### DETAILED DESCRIPTION OF THE INVENTION

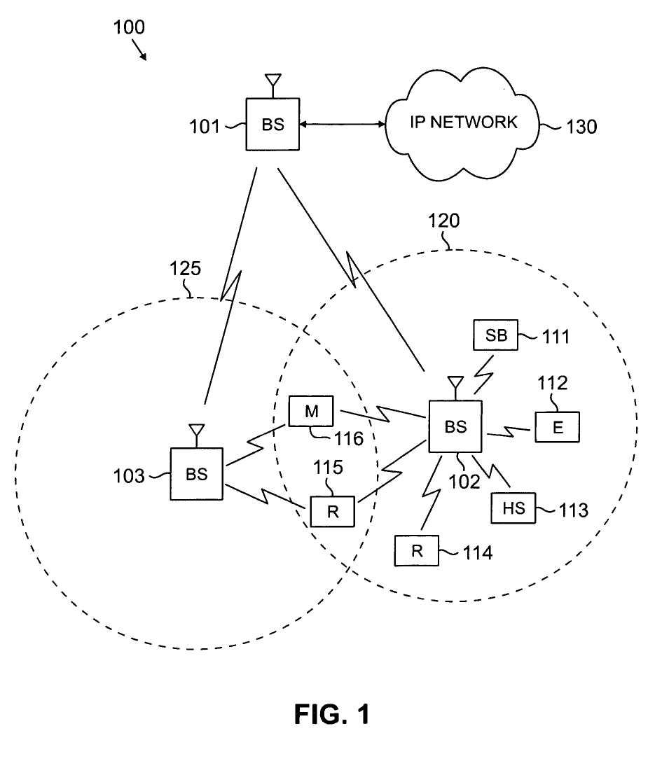

FIGS. 1 through 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless network.

FIG. 1 illustrates exemplary wireless network 100 that is suitable for providing channel estimation and interference cancellation according to one embodiment of the present disclosure. In the illustrated embodiment, wireless network 100 includes base station (BS) 101, base station (BS) 102, and base station (BS) 103. Base station 101 communicates with base station 102 and base station 103. Base station 101 also communicates with Internet protocol (IP) network 130, such as the Internet, a proprietary IP network, or other data network.

Base station 102 provides wireless broadband access to network 130, via base station 101, to a first plurality of subscriber stations within coverage area 120 of base station 102. The first plurality of subscriber stations includes subscriber station (SS) 111, subscriber station (SS) 112, subscriber station (SS) 113, subscriber station (SS) 114, subscriber station (SS) 115 and subscriber station (SS) 116. In an exemplary embodiment, SS 111 may be located in a small business (SB), SS 112 may be located in an enterprise (E), SS 113 may be located in a WiFi hotspot (HS), SS 114 may be located in a first residence, SS 115 may be located in a second residence, and SS 116 may be a mobile (M) device.

Base station 103 provides wireless broadband access to network 130, via base station 101, to a second plurality of subscriber stations within coverage area 125 of base station 103. The second plurality of subscriber stations includes subscriber station 115 and subscriber station 116. In alternate embodiments, base stations 102 and 103 may be connected directly to the Internet by means of a wired broadband connection, such as an optical fiber, DSL, cable or T1/E1 line, rather than indirectly through base station 101.

In other embodiments, base station 101 may be in communication with either fewer or more base stations. Furthermore, while only six subscriber stations are shown in FIG. 1, it is understood that wireless network 100 may provide wireless broadband access to more than six subscriber stations. It is noted that subscriber station 115 and subscriber station 116 are on the edge of both coverage area 120 and coverage area 125. Subscriber station 115 and subscriber station 116 each communicate with both base station 102 and base station 103 and may be said to be operating in handoff mode, as known to those of skill in the art.

In an exemplary embodiment, base stations 101-103 may communicate with each other and with subscriber stations 111-116 using an IEEE-802.16 wireless metropolitan area network standard, such as, for example, an IEEE-802.16e standard. In another embodiment, however, a different wireless protocol may be employed, such as, for example, a HIPERMAN wireless metropolitan area network standard. Base station 101 may communicate through direct line-of-sight or non-line-of-sight with base station 102 and base station 103, depending on the technology used for the wireless backhaul. Base station 102 and base station 103 may each communicate through non-line-of-sight with subscriber stations 111-116 using OFDM and/or OFDMA techniques.

Base station 102 may provide a T1 level service to subscriber station 112 associated with the enterprise and a fractional T1 level service to subscriber station 111 associated with the small business. Base station 102 may provide wireless backhaul for subscriber station 113 associated with the WiFi hotspot, which may be located in an airport, café, hotel, or college campus. Base station 102 may provide digital subscriber line (DSL) level service to subscriber stations 114, 115 and 116.

Subscriber stations 111-116 may use the broadband access to network 130 to access voice, data, video, video teleconferencing, and/or other broadband services. In an exemplary embodiment, one or more of subscriber stations 111-116 may be associated with an access point (AP) of a WiFi WLAN. Subscriber station 116 may be any of a number of mobile devices, including a wireless-enabled laptop computer, personal data assistant, notebook, handheld device, or other wireless-enabled device. Subscriber stations 114 and 115 may be, for example, a wireless-enabled personal computer, a laptop computer, a gateway, or another device.

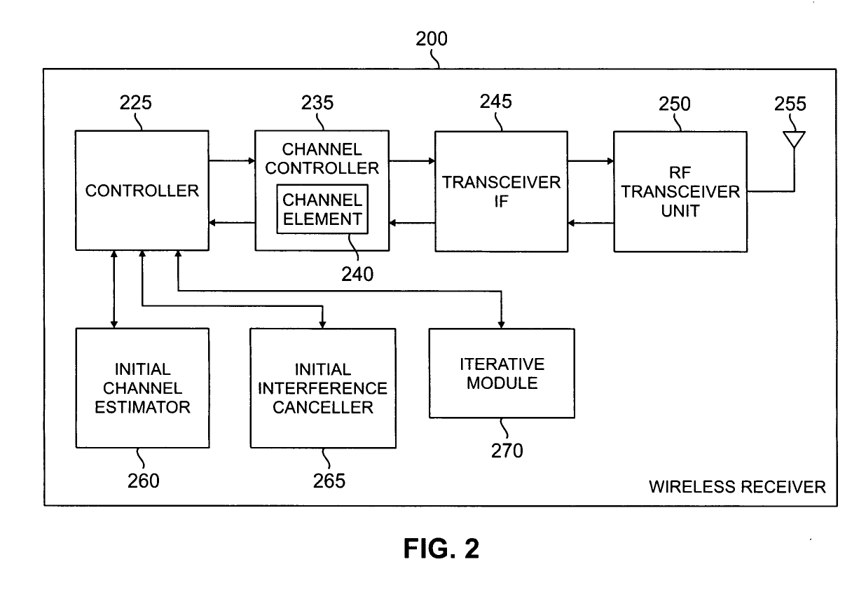

In accordance with an embodiment of the present disclosure, each base station 101-103 and/or other wireless receiver in network 100 is operable to provide channel estimation and interference cancellation for transmissions from the subscriber stations 111-116 by using an iterative method that results in progressively better channel estimates and interference cancellation. In performing this iterative method, the base station 101-103 or other wireless receiver first estimates the channel response fairly reliably based on the fact that multiple OFDM symbols exist in a single transmit time interval (TTI), or sub-frame. The base station 101-103 or other wireless receiver obtains a channel response estimate for one TTI by treating the individual channel response estimates obtained from each OFDM symbol as observation samples. After obtaining an initial channel response estimate, the base station 101-103 or other wireless receiver is able to improve that estimate using the iterative method, as described in more detail below in connection with FIGS. 2-4.

Dotted lines show the approximate extents of coverage areas 120 and 125, which are shown as approximately circular for the purposes of illustration and explanation only. It should be clearly understood that the coverage areas associated with base stations, for example, coverage areas 120 and 125, may have other shapes, including irregular shapes, depending upon the configuration of the base stations and variations in the radio environment associated with natural and man-made obstructions.

Also, the coverage areas associated with base stations are not constant over time and may be dynamic (expanding or contracting or changing shape) based on changing transmission power levels of the base station and/or the subscriber stations, weather conditions, and other factors. In an embodiment, the radius of the coverage areas of the base stations, for example, coverage areas 120 and 125 of base stations 102 and 103, may extend in the range from less than 2 kilometers to about fifty kilometers from the base stations.

As is well known in the art, a base station, such as base station 101, 102, or 103, may employ directional antennas to support a plurality of sectors within the coverage area. In FIG. 1, base stations 102 and 103 are depicted approximately in the center of coverage areas 120 and 125, respectively, In other embodiments, the use of directional antennas may locate the base station near the edge of the coverage area, for example, at the point of a cone-shaped or pear-shaped coverage area.

The connection to network 130 from base station 101 may comprise a broadband connection, for example, a fiber optic line, to servers located in a central office or another operating company point-of-presence. The servers may provide communication to an Internet gateway for internet protocol-based communications and to a public switched telephone network gateway for voice-based communications. In the case of voice-based communications in the form of voice-over-IP (VoIP), the traffic may be forwarded directly to the Internet gateway instead of the PSTN gateway. The servers, Internet gateway, and public switched telephone network gateway are not shown in FIG. 1. In another embodiment, the connection to network 130 may be provided by different network nodes and equipment.

FIG. 2 illustrates a wireless receiver 200 in greater detail according to one embodiment of the present disclosure. The wireless receiver 200 is illustrated by way of example only. In one embodiment, the wireless receiver 200 comprises controller 225, channel controller 235, transceiver interface (IF) 245, radio frequency (RF) transceiver unit 250, antenna array 255, initial channel estimator 260, initial interference canceller 265, and iterative module 270.

Controller 225 comprises processing circuitry and memory capable of executing an operating program that controls the overall operation of the receiver 200. Under normal conditions, controller 225 directs the operation of channel controller 235, which comprises a number of channel elements, such as exemplary channel element 240, each of which performs bidirectional communication in the forward channel and the reverse channel. Channel element 240 also preferably performs all baseband processing, including processing any digitized received signal to extract the information or data bits conveyed in the received signal, typically including demodulation, decoding, and error correction operations, as known to those of skill in the art. Transceiver IF 245 transfers bidirectional channel signals between channel controller 235 and RF transceiver unit 250.

Although illustrated and described as three separate components, it will be understood that any two or more of initial channel estimator 260, initial interference canceller 265 and iterative module 270 may be implemented together in a single component without departing from the scope of the present disclosure.

Initial channel estimator 260 is operable to estimate the channel response based on data received from controller 225. Initial channel estimator 260 is operable to generate a relatively reliable initial channel estimate. For example, initial channel estimator 260 may be operable to generate the initial channel estimate by averaging channel estimates for multiple or all OFDM symbols in a single sub-frame. Initial channel estimator 260 is also operable to provide the initial channel estimate to controller 225 or, as an alternative, to iterative module 270.

Initial interference canceller 265 is operable to cancel interference from received signals Initial interference canceller 265 is also operable to provide the interference-cancelled signals to controller 225 and/or, as described below, to iterative module 270. An interference-cancelled signal generated by initial interference canceller 265 is referred to as a received signal with initial interference cancellation (RS_{iic}).

Iterative module 270 is operable to receive the initial channel estimate generated by initial channel estimator 260 and the RS_{iic} generated by initial interference canceller 265. Although illustrated as coupled to controller 225 and operable to receive data from controller 225, it will be understood that iterative module 270 may also be coupled to initial channel estimator 260 and/or initial interference canceller 265 and be operable to receive data from these components 260 and/or 265 without departing from the scope of the present disclosure. For this embodiment, iterative module 270 may receive the initial channel estimate from initial channel estimator 260 and/or may receive the RS_{iic} from initial interference canceller 265.

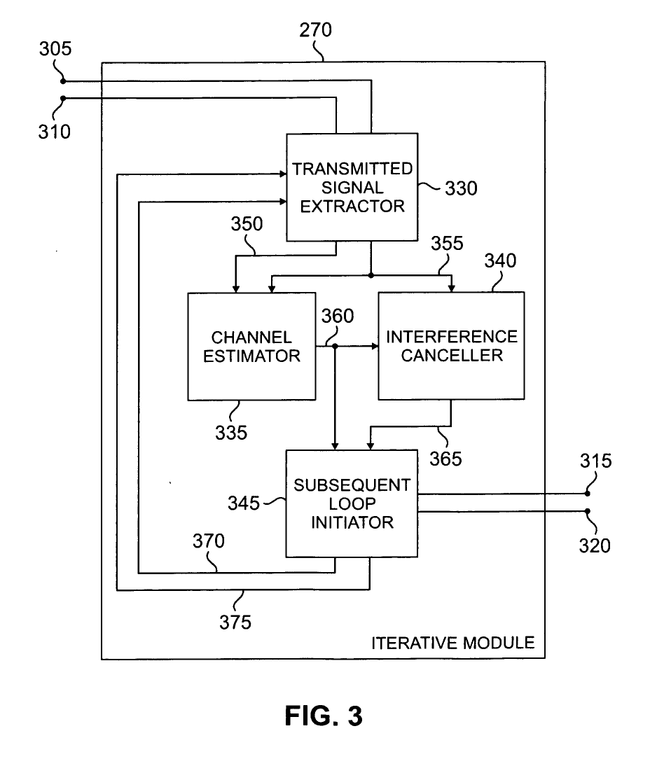

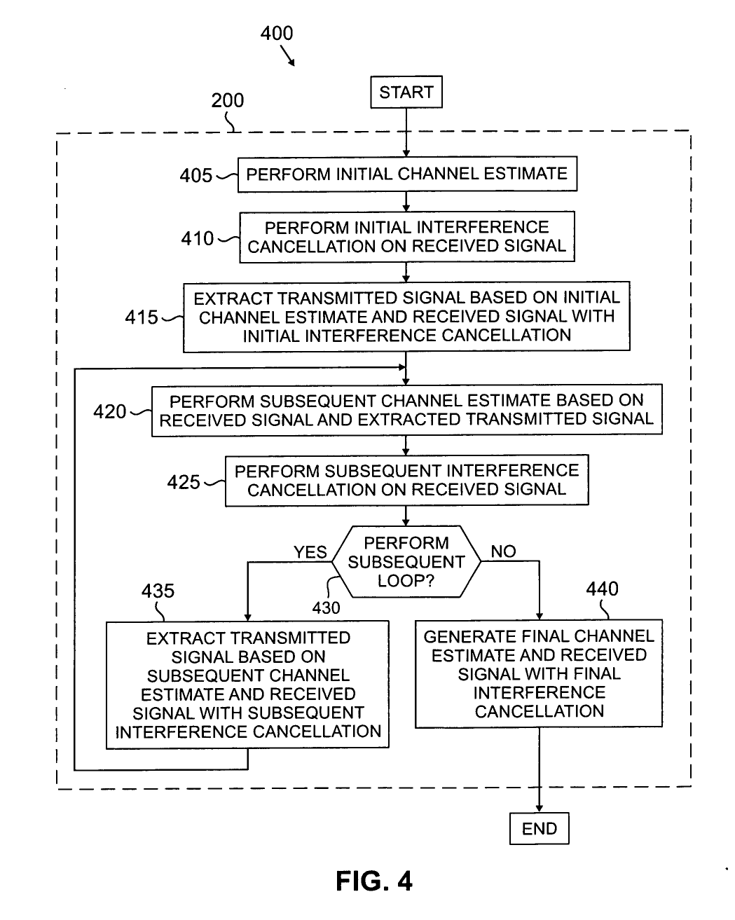

As described in more detail below in connection with FIGS. 3 and 4, iterative module 270 is operable to perform an iterative process to generate successively more accurate channel estimates and more accurate cancellation of interference. For an alternative embodiment, iterative module 270 may be operable to receive either the initial channel estimate or the RS_{iic} and may be operable to perform the iterative process to generate either the more accurate channel estimate or the more accurate cancellation of interference.

For one embodiment, iterative module 270 is operable to estimate the channel and/or cancel interference by determining the transmitted signal based on the initial or most recent channel estimate, cleaning up the transmitted signal using symbol slicing or other suitable data integrity checking method, estimating the channel based on the cleaned up transmitted signal and the received signal, and performing interference cancellation based on the new channel estimate. Iterative module 270 is then operable to determine whether or not to perform a subsequent iteration. This determination may be based on the number of previous iterations performed, a change in consecutive channel estimates and/or cancelled interference that is below a predetermined threshold, or any other suitable criteria.

FIG. 3 illustrates details of the iterative module 270 of wireless receiver 200 according to an embodiment of the present disclosure. Iterative module 270 is operable to receive the initial channel estimate 305 generated by initial channel estimator 260 and the RS_{iic} 310 generated by initial interference canceller 265. As described above, one or both of these signals 305 and 310 may be received from controller 225, the initial channel estimate 305 may be received from initial channel estimator 260 and/or the RS_{iic} 310 may be received from initial interference canceller 265.

Based on these signals 305 and 310, iterative module 270 is operable to generate a final channel estimate 315 and a received signal with final interference cancellation (RS_{fic}) 320. To generate these signals 315 and 320, iterative module 270 comprises a transmitted signal extractor 330, a channel estimator 335, an interference canceller 340, and a subsequent loop initiator 345.

Although illustrated and described as four separate components, it will be understood that any two or more of transmitted signal extractor 330, channel estimator 335, interference canceller 340, and subsequent loop initiator 345 may be implemented together in a single component without departing from the scope of the present disclosure.

For one embodiment, transmitted signal extractor 330 is operable to receive the initial channel estimate 305 and the RS_{iic} 310 and, based on these signals 305 and 310, to generate an extracted transmitted signal 350 and a received signal with interference cancellation (RS_{ic}) 355. For a particular embodiment, transmitted signal extractor 330 is operable to generate the extracted transmitted signal 350 initially by determining the transmitted signal based on the initial channel estimate 305 and the RS_{iic} 310 and then cleaning up the transmitted signal using symbol slicing or other suitable data integrity checking method. Transmitted signal extractor 330 may also be operable to generate the RS_{ic} 355 initially by passing through the RS_{iic} 310. Thus, the RS_{ic} 355 is initially equivalent to the RS_{iic} 310.

Transmitted signal extractor 330 is operable to provide the extracted transmitted signal 350 to channel estimator 335 and may be operable to provide the RS_{ic} 355 to channel estimator 335 and interference canceller 340. For an alternative embodiment, the RS_{iic} 310 may be provided directly to channel estimator 335 and interference canceller 340, in addition to transmitted signal extractor 330. For this embodiment, transmitted signal extractor 330 may not provide the RS_{ic} 355 to channel estimator 335 and interference canceller 340.

Channel estimator 335 is coupled to transmitted signal extractor 330 and is operable to receive the extracted transmitted signal 350 and, in some embodiments, the RS_{ic} 355 from transmitted signal extractor 330. Based on these signals 350 and 355, channel estimator 335 is operable to generate a subsequent channel estimate 360. For one embodiment, channel estimator 335 is operable to generate the subsequent channel estimate 360 by averaging channel estimates for multiple or all OFDM symbols in a single sub-frame.

Channel estimator 335 is also operable to provide the subsequent channel estimate 360 to interference canceller 340 and to subsequent loop initiator 345. For an alternative embodiment, channel estimator 335, instead of transmitted signal extractor 330, may be operable to provide the RS_{ic} 355 to interference canceller 340.

Interference canceller 340 is coupled to channel estimator 335 and, for the embodiment in which transmitted signal extractor 330 provides the RS_{ic} 355 to interference canceller 340, is also coupled to transmitted signal extractor 330. Interference canceller 340 is operable to receive the RS_{ic} 355 from transmitted signal extractor 330 or channel estimator 335 and is operable to receive the subsequent channel estimate 360 from channel estimator 335. Based on these signals 355 and 360, interference canceller 340 is operable to generate a received signal with subsequent interference cancellation (RS_{sic}) 365 and to provide the RS_{sic} 365 to subsequent loop initiator 345.

Subsequent loop initiator 345 is coupled to channel estimator 335 and interference canceller 340 and is operable to receive the subsequent channel estimate 360 from channel estimator 335 and the RS_{sic} 365 from interference canceller 340. Based on these signals 360 and 365, subsequent loop initiator 345 may be operable to generate a subsequent channel estimate 370 and a received signal with subsequent interference cancellation (RS_{sic}) 375 or the final channel estimate 315 and the received signal with final interference cancellation (RS_{fic}) 320.

Subsequent loop initiator 340 is operable to determine whether or not a subsequent loop is to be performed by iterative module 270 in order to generate more accurate channel estimates and interference cancellation. For example, subsequent loop initiator 345 may be operable to determine whether a particular number of loops have been completed or whether a change in channel estimates and/or interference cancellation from one loop to the next is below a predetermined threshold. For one embodiment, the particular number of completed loops may comprise three or four. However, it will be understood that subsequent loop initiator 345 may make the determination in any other suitable manner without departing from the scope of the present disclosure.

When subsequent loop initiator 345 determines that iterative module 270 should perform another loop to generate more accurate channel estimates and/or interference cancellation, subsequent loop initiator 345 is operable to generate the subsequent channel estimate 370, which is equivalent to the subsequent channel estimate 360, and the RS_{sic} 375, which is equivalent to the RS_{sic} 365. Subsequent loop initiator 345 is then operable to provide these signals 370 and 375 to transmitted signal extractor 330.

Transmitted signal extractor 330 is coupled to subsequent loop initiator 345 and is operable to receive these signals 370 and 375 from subsequent loop initiator 345. Based on receiving these signals, transmitted signal extractor 330 is operable to begin a subsequent loop. As an alternative embodiment, channel estimator 335 and/or interference canceller 340 may be operable to provide the signals 360 and/or 365 to transmitted signal extractor 330 based on a signal from subsequent loop initiator 345. As another alternative, channel estimator 335 and/or interference canceller 340 may be operable to provide the signals 360 and/or 365 to transmitted signal extractor 330 continuously, and subsequent loop initiator 345 may be operable to provide an initiation signal to transmitted signal extractor 330 when subsequent loop initiator 345 determines that iterative module 270 should perform another loop. It will be understood that other suitable alternatives may be implemented without departing from the scope of the present disclosure.

When subsequent loop initiator 345 prompts transmitted signal extractor 330 to initiate a subsequent loop, transmitted signal extractor 330 is operable to receive the subsequent channel estimate 360 or 370 and the RS_{sic} 365 or 375 and, based on these signals 360/370 and 365/375, to generate a subsequent extracted transmitted signal 350 and a subsequent RS_{ic} 355. Transmitted signal extractor 330 may also be operable to generate the RS_{ic} 355 in subsequent loops by passing through the RS_{sic} 360/370. Thus, the RS_{ic} 355 is equivalent to the RS_{sic} 360/370 in subsequent loops.

When subsequent loop initiator 345 determines that iterative module 270 need not perform another loop to generate more accurate channel estimates and/or interference cancellation, subsequent loop initiator 345 is operable to generate the final channel estimate 315, which is equivalent to the subsequent channel estimate 360, and the RS_{fic} 320, which is equivalent to the RS_{sic} 365. Subsequent loop initiator 345 is then operable to provide these signals 315 and 320 as an output of iterative module 270.

It will be understood that other alternatives may be implemented without departing from the scope of the present disclosure. For example, channel estimator 335 may be operable to provide the subsequent channel estimate 360 only to interference canceller 340, and interference canceller 340 may be operable to provide the subsequent channel estimate 360 to subsequent loop initiator 345. Other similar alterations may be made to the manner in which any of the signals are provided between the components 330, 335, 340 and 345.

FIG. 4 is a flow diagram illustrating a method 400 for channel estimation and interference cancellation in a wireless receiver, such as wireless receiver 200, according to a particular embodiment of the present disclosure. It will be understood that the method described is one particular embodiment and that modifications such as those described in connection with FIG. 3 may be made to the details of the method without departing from the scope of the present disclosure.

Initially, initial channel estimator 260 performs an initial channel estimate by any suitable means operable to generate a relatively accurate initial channel estimate 305 (process step 405). Initial interference canceller 265 performs an initial interference cancellation on a signal received at the receiver 200 using any suitable interference cancellation method (process step 410). By canceling the interference in the received signal, initial interference canceller 265 generates an RS_{iic} 310.

Based on the initial channel estimate 305 and the RS_{iic} 310, transmitted signal extractor 330 extracts the transmitted signal 350 (process step 415). For one embodiment, transmitted signal extractor 330 extracts the transmitted signal 350 by determining the transmitted signal based on the received signal with interference cancellation and the most recent channel estimate and then cleaning up the transmitted signal using symbol slicing or other suitable data integrity checking method.

Channel estimator 335 performs a subsequent channel estimate based on the extracted transmitted signal 350 and based on the RS_{ic} 355, which corresponds to the most recently interference-canceled received signal, to generate a subsequent channel estimate 360 (process step 420). For one embodiment, channel estimator 335 generates the subsequent channel estimate 360 by averaging channel estimates for multiple or all OFDM symbols in a particular sub-frame.

Interference canceller 340 performs a subsequent interference cancellation on the received signal based on the RS_{ic} 355, which corresponds to the most recently interference-canceled received signal, and the subsequent channel estimate 360 generated by channel estimator 335 to generate an RS_{sic} 365 (process step 425).

Subsequent loop initiator 345 makes a determination regarding whether or not iterative module 270 should perform a subsequent loop in order to achieve a more accurate channel estimate and/or interference cancellation (process step 430). For example, subsequent loop initiator 345 may make the determination regarding whether or not iterative module 270 should perform a subsequent loop based on the number of previous iterations performed, a change in consecutive channel estimates and/or cancelled interference that is below a predetermined threshold, or any other suitable criteria.

If subsequent loop initiator 345 determines that iterative module 270 should perform a subsequent loop (process step 430), transmitted signal extractor 330 extracts the transmitted signal 350 as transmitted by the transmitter based on the subsequent channel estimate 370 and the RS_{sic} 375 provided by subsequent loop initiator 345 (process step 435). Alternatively, transmitted signal extractor 330 may generate the extracted transmitted signal 350 based on the subsequent channel estimate 360 provided by channel estimator 335 and the RS_{sic} 365 provided by interference canceller 340. After the transmitted signal 350 is extracted for the subsequent loop, channel estimator 335 performs yet another channel estimate based on the most recently generated signals 350 and 355 provided by transmitted signal extractor 330 (process step 420), and the method continues as before.

Once subsequent loop initiator 345 determines that iterative module 270 need not perform a subsequent loop (process step 430), subsequent loop initiator 345 generates the final channel estimate 315, which corresponds to the most recently generated subsequent channel estimate 360, and the RS_{fic} 320, which corresponds to the most recently generated RS_{sic} 365 (process step 440), at which point the method comes to an end.

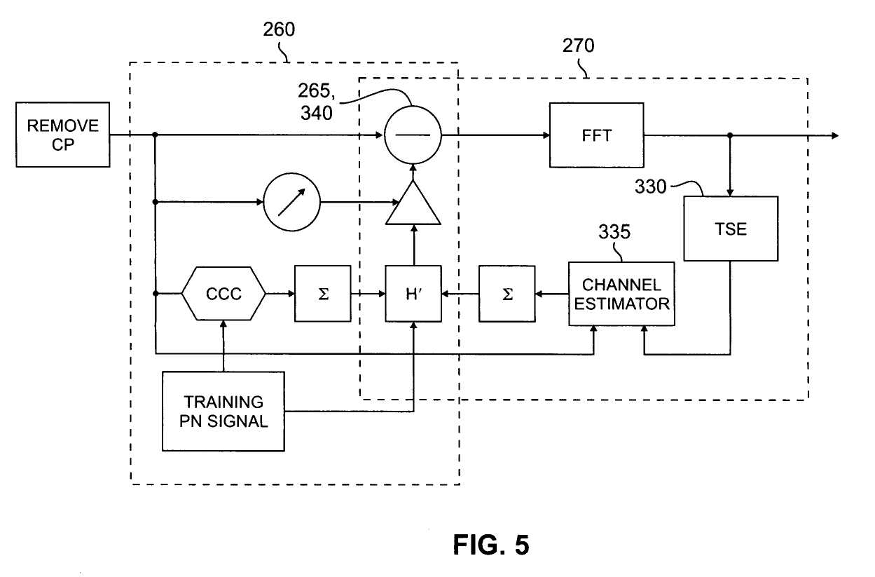

FIG. 5 illustrates details of a wireless receiver, such as the wireless receiver 200, according to an embodiment of the present disclosure. FIG. 5 illustrates one particular embodiment of initial channel estimator 260, initial interference canceller 265 and iterative module 270, which are operable to receive a transmitted signal with a cyclic prefix (CP) removed.

After a Fast Fourier Transform (FFT) operation in iterative module 270, a soft decision on the information/data symbols is made by symbol slicing based on the modulation scheme or by any other suitable data integrity checking method in transmitted signal extractor (TSE) 330. Channel estimator 335 then obtains a new channel estimation update from the detected symbols and the received raw data. For each OFDM symbol, one channel estimation update may be obtained. For example, if there are eight OFDM symbols in a sub-frame, channel estimator 335 may obtain eight channel estimation updates and average the eight updates to obtain one channel estimation update for the current sub-frame.

The channel impulse response (CIR) is obtained by an inverse Fourier transform of the averaged frequency domain channel estimate and by zeroing out the portion of the IFFT result using prior knowledge about the maximum delay spread of the wireless channel being estimated. This has the effect of reducing the noise component in the estimated channel. In another embodiment, it is possible to zero out all but the L strongest time domain components. For a particular embodiment, L may comprise 6. This completes the first iteration of decision feedback-based channel estimation updating.

Once the new channel estimation update is obtained, a new round/iteration of interference cancellation may be performed by passing the training PN signal through a filter with the newly updated channel impulse response. The output of the filter, which is the updated interference estimate, is then scaled properly and subtracted from the received raw data. This completes the first iteration of interference cancellation. The entire decision feedback channel estimation and interference cancellation may be repeated. Certain criteria may be used to determine if further iteration processes are to be performed. One such criterion is the difference between the current channel estimate update and the result from the previous iteration. Others may include a number of previous iterations performed, a difference between the current amount of interference cancelled and the amount cancelled in the previous iteration, or any other suitable criteria.

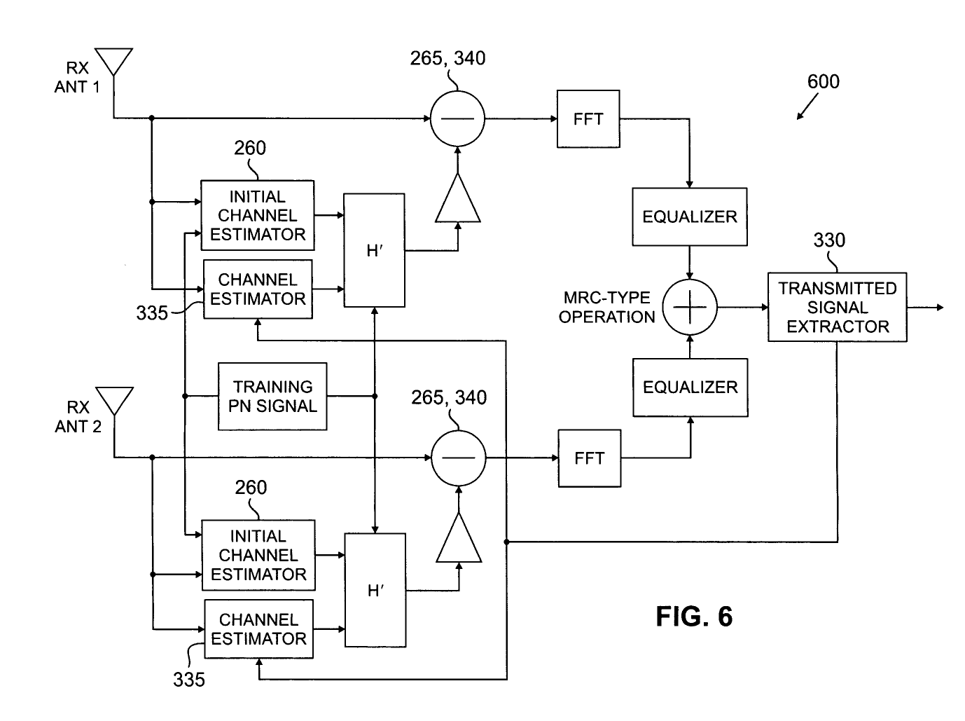

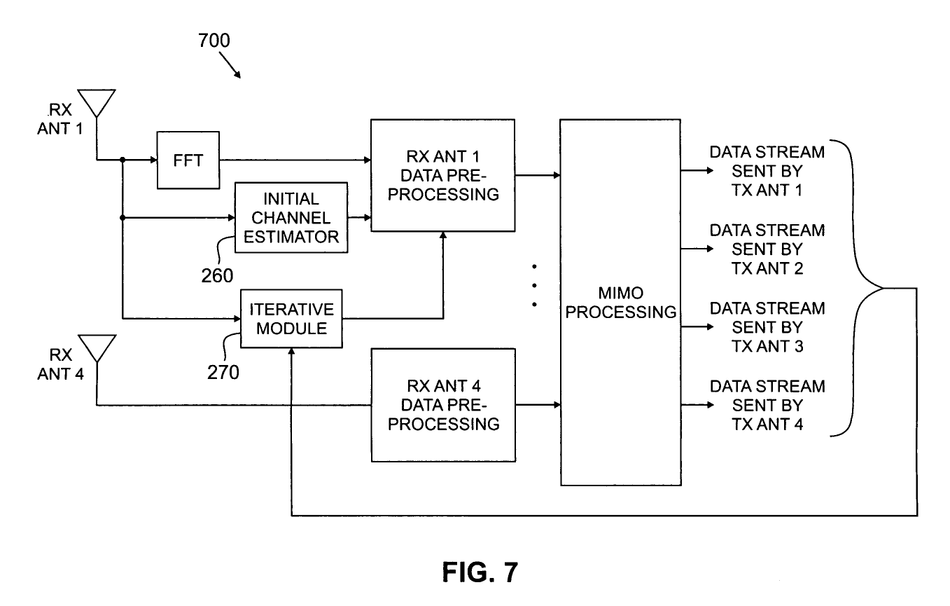

FIG. 6 illustrates an implementation of a portion of a wireless receiver, such as the wireless receiver 200, in a 1×2 SIMO system 600 according to a particular embodiment of the present disclosure. FIG. 7 illustrates an implementation of a portion of a receiver, such as the wireless receiver 200, in a 4×4 MIMO system 700 according to another particular embodiment of the present disclosure. A general approach to decision feedback channel estimation in accordance with the present disclosure is described below and may be implemented as system 600, system 700 or other suitable system.

Assume a multiple antenna system has M transmit antennas and N receives antennas. The m is the transmit antenna index going from 1 to M. The n is the transmit antenna index going from 1 to N. Then

$${h}_{n , m} ( z , t ) = {\sum }_{l = 0}^{L - 1} {h}_{l} ( t ) \cdot {z}^{- l} \qquad ( 1 )$$

is the impulse response of the channel at time instant t from the transmit antenna m to the receive antenna n. In the above equation, L is the number of multipaths. The Discrete Fourier Transform (DFT) of h_{m,n}(z,t) is represented by
H_{n,m}(k,t)=DFT(h_{n,m}(z,t)). (2)

The received signal at subcarrier k of the receive antenna n may be written as

$${r}_{n} ( t , k ) = {\sum }_{m = 1}^{M} {H}_{n , m} ( t , k ) \cdot {s}_{m} ( t , k ) + {w}_{n} ( t , k ) , \qquad ( 3 )$$

where sₘ(t,k) is the information symbol sent by the transmit antenna m at subcarrier k and time instant t, and wₙ(t,k) is the noise component at the receiver n.

For simplicity, a 2×2 system having two transmit antennas and two receive antennas will be used as an example to explain the decision feedback assisted channel estimation procedure according to this embodiment. However, it will be understood that the concept may be extended to cases where M and/or N are not equal to 2.

In the 2×2 case, the received signal at subcarrier k of a given antenna may be written as

$$r ( t , k ) = [ \begin{matrix}{s}_{1} ( t , k ) & {s}_{2} ( t , k )\end{matrix} ] [ \begin{matrix}{H}_{1} ( t , k ) \\ {H}_{2} ( t , k )\end{matrix} ] + w ( t , k ) . \qquad ( 4 )$$

Note that the receiver subscript n has been omitted in Equation 4 for further clarity. If the frequency domain channel responses H₁(t,k) and H₂(t,k) remain unchanged from time instant t₁ to t₂,

$$[ \begin{matrix}r ( {t}_{1} , k ) \\ r ( {t}_{2} , k )\end{matrix} ] = [ \begin{matrix}{s}_{1} ( {t}_{1} , k ) & {s}_{2} ( {t}_{1} , k ) \\ {s}_{1} ( {t}_{2} , k ) & {s}_{2} ( {t}_{2} , k )\end{matrix} ] [ \begin{matrix}{H}_{1} ( {t}_{1 , 2} , k ) \\ {H}_{2} ( {t}_{1 , 2} , k )\end{matrix} ] + [ \begin{matrix}w ( {t}_{1} , k ) \\ w ( {t}_{2} , k )\end{matrix} ] , \qquad ( 5 )$$

where the notation t_{1,2} has been used to indicate that the quantity is good for both time instants t₁ and t₂.

Equation 3 is the system model establishing the relationship between the received data and the channel frequency response (CFR) via the transmitted information symbols. This system model described in Equation 3 is called the forward CFR-Data relationship. In the case of a 2×2 MIMO system, the corresponding backward CFR-Data relationship may be obtained by solving Equation 5 for channel frequency responses in a least-square sense as follows:

$$[ \begin{matrix}{H}_{1} ( {t}_{1 , 2} , k ) \\ {H}_{2} ( {t}_{1 , 2} , k )\end{matrix} ] = {[ \begin{matrix}{s}_{1} ( {t}_{1} , k ) & {s}_{2} ( {t}_{1} , k ) \\ {s}_{1} ( {t}_{2} , k ) & {s}_{2} ( {t}_{2} , k )\end{matrix} ]}^{- 1} [ \begin{matrix}r ( {t}_{1} , k ) \\ r ( {t}_{2} , k )\end{matrix} ] . \qquad ( 6 )$$

In addition to the least-square solution to the channel frequency responses, other types of solutions exist because the frequency responses are random variables in nature. In certain scenarios, it may be preferable to use the minimum mean square error estimates (MMSE) of the channel frequency responses, even considering the cost of increased computational complexity.

The backward CFR-Data relationship described in Equation 6 is established under the assumption that the channel response may be considered unchanged in subsequent time instants. A similar relationship may be established across consecutive frequency subcarriers if the channel responses may be considered flat among a certain number of neighboring subcarriers. In this scenario, for the case of two consecutive subcarriers, the backward CFR-Data relationship may be established by first setting up the following system of equations:

$$[ \begin{matrix}r ( t , {k}_{1} ) \\ r ( t , {k}_{2} )\end{matrix} ] = [ \begin{matrix}{s}_{1} ( t , {k}_{1} ) & {s}_{2} ( t , {k}_{1} ) \\ {s}_{1} ( t , {k}_{2} ) & {s}_{2} ( t , {k}_{2} )\end{matrix} ] [ \begin{matrix}{H}_{1} ( t , {k}_{1 , 2} ) \\ {H}_{2} ( t , {k}_{1 , 2} )\end{matrix} ] + [ \begin{matrix}w ( t , {k}_{1} ) \\ w ( t , {k}_{2} )\end{matrix} ] . \qquad ( 7 )$$

The notation k_{1,2} has been used to indicate that the quantity is good for both subcarriers k₁ and k₂. The backward CFR-Data relationship may be obtained by solving the above system in a least-squares or MMSE sense.

In fact, when the channel responses may be considered flat in both time and frequency, an over-determined system may be set up by combining Equations 5 and 7 as illustrated below:

$$[ \begin{matrix}r ( {t}_{1} , {k}_{1} ) \\ r ( {t}_{1} , {k}_{2} ) \\ r ( {t}_{2} , {k}_{1} ) \\ r ( {t}_{2} , {k}_{2} )\end{matrix} ] = [ \begin{matrix}{s}_{1} ( {t}_{1} , {k}_{1} ) & {s}_{1} ( {t}_{1} , {k}_{1} ) \\ {s}_{1} ( {t}_{1} , {k}_{2} ) & {s}_{1} ( {t}_{1} , {k}_{2} ) \\ {s}_{1} ( {t}_{2} , {k}_{1} ) & {s}_{1} ( {t}_{2} , {k}_{1} ) \\ {s}_{1} ( {t}_{2} , {k}_{2} ) & {s}_{1} ( {t}_{2} , {k}_{2} )\end{matrix} ] [ \begin{matrix}{H}_{1} ( {t}_{1 , 2} , {k}_{1 , 2} ) \\ {H}_{2} ( {t}_{1 , 2} , {k}_{1 , 2} )\end{matrix} ] + [ \begin{matrix}w ( {t}_{1} , {k}_{1} ) \\ w ( {t}_{1} , {k}_{2} ) \\ w ( {t}_{2} , {k}_{1} ) \\ w ( {t}_{2} , {k}_{2} )\end{matrix} ] . \qquad ( 8 )$$

The minimum number of rows in Equations 5 and 7 is two for a 2×2 MIMO system. This number may increase to enhance the noise-eliminating capability depending on the channel condition.

With the establishment of the forward and backward CFR-Data relationships, the channel estimation and interference cancellation procedure for this embodiment may be described as follows:
1) With the aid of the training signal (symbols), an initial channel estimate may be obtained via the forward CFR-Data relationship.
2) Using the initial channel estimate, received data may be equalized and demodulated to obtain estimates of transmitted information symbols.
3) Constellation slicing may be performed to get hard decisions on the information symbols.
4) Using the received data and the “hard” decision of the information symbols, a system of equations, such as those in (5), (7) or (8), may be set up depending on the channel conditions.
5) A new channel estimate is obtained by solving the system of equations in either a least-square or MMSE sense.
6) Steps 2 through 5 may be repeated based on established criteria.

In another embodiment of the current disclosure, multiple pilot signals from multiple antennas may be used for MIMO (Multiple Input Multiple Output) channel estimation. These multiple training signals may be embedded below the transmitted information data or transmitted using orthogonal subcarriers (or orthogonal codes) to data subcarriers (or data codes). The two training sequences from the two antennas may be used for channel response estimate updates by decision feedback according to the principles of the current disclosure.

In an OFDM system, in order to have a good channel estimate in both the frequency domain and the time domain, the reference pilot symbols are carried in the frequency-time grid. For example, a frequency-time pilot transmission approach where the pilots are distributed both in frequency and time may be implemented. The total frequency resource is divided into subbands. Also, possibly multiple OFDM symbols (e.g., eight) are transmitted within a sub-frame carrying an information block. A minimum of one reference pilot symbol is used in each of the subbands and also in each of the OFDM symbols per antenna per sub-frame. The subcarrier resource overhead due to pilots would then be determined based on how many subcarriers within a subband are used for pilot, the number of subbands, and the number of OFDM symbols within a sub-frame. The reliability of the channel estimation may be controlled by varying the power on the reference pilot subcarriers.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A method of channel estimation and interference cancellation in an Orthogonal Frequency Division Multiple Access (OFDMA) network, comprising:
determining an estimate of a transmitted signal based on an initial channel estimate and a received signal;
generating an extracted transmitted signal based on the estimate of the transmitted signal using a data integrity checking method; and
generating a subsequent channel estimate based on the received signal and the extracted transmitted signal.

2. The method as set forth in claim 1, further comprising determining whether a subsequent iteration criterion has been met.

3. The method as set forth in claim 2, further comprising, when the subsequent iteration criterion has been met:
determining a subsequent estimate of the transmitted signal based on the subsequent channel estimate and the received signal;
generating a subsequent extracted transmitted signal based on the subsequent estimate of the transmitted signal using a data integrity checking method; and
generating an additional subsequent channel estimate based on the received signal and the subsequent extracted transmitted signal.

4. The method as set forth in claim 2, the subsequent iteration criterion comprising at least one of a predetermined number of iterations having been performed and a difference between consecutive channel estimates that is below a predetermined threshold.

5. The method as set forth in claim 1, generating the subsequent channel estimate based on the received signal and the extracted transmitted signal comprising generating the subsequent channel estimate by averaging channel estimates for a plurality of OFDM symbols in a single transmit time interval.

6. The method as set forth in claim 1, the received signal comprising a received signal on which interference cancellation has been performed.

7. The method as set forth in claim 1, further comprising canceling interference in the received signal based on the subsequent channel estimate.

8. The method as set forth in claim 1, the data integrity checking method comprising symbol slicing.

9. A wireless receiver capable of providing channel estimation and interference cancellation in an Orthogonal Frequency Division Multiple Access (OFDMA) network, comprising:
an initial channel estimator operable to generate an initial channel estimate; and
an iterative module operable to determine an estimate of a transmitted signal based on an initial channel estimate and a received signal, to generate an extracted transmitted signal based on the estimate of the transmitted signal using a data integrity checking method, to generate a subsequent channel estimate based on the received signal and the extracted transmitted signal, and to determine whether a subsequent iteration criterion has been met.

10. The wireless receiver as set forth in claim 9, the iterative module further operable, when the subsequent iteration criterion has been met, to determine a subsequent estimate of the transmitted signal based on the subsequent channel estimate and the received signal, to generate a subsequent extracted transmitted signal based on the subsequent estimate of the transmitted signal using a data integrity checking method, and to generate an additional subsequent channel estimate based on the received signal and the subsequent extracted transmitted signal.

11. The wireless receiver as set forth in claim 10, the iterative module further operable, when the subsequent iteration criterion has not been met, to provide as a final channel estimate the most recently generated subsequent channel estimate.

12. The wireless receiver as set forth in claim 9, the subsequent iteration criterion comprising at least one of a predetermined number of iterations having been performed and a difference between consecutive channel estimates that is below a predetermined threshold.

13. The wireless receiver as set forth in claim 9, the iterative module operable to generate the subsequent channel estimate based on the received signal and the extracted transmitted signal by averaging channel estimates for a plurality of OFDM symbols in a single transmit time interval.

14. The wireless receiver as set forth in claim 9, further comprising an initial interference canceller operable to cancel interference in the received signal to generate an interference-canceled signal, the iterative module further operable to cancel interference in the interference-canceled signal based on the subsequent channel estimate.

15. The wireless receiver as set forth in claim 9, the data integrity checking method comprising symbol slicing.

16. A wireless receiver capable of providing channel estimation and interference cancellation in an orthogonal Frequency Division Multiple Access (OFDMA) network, comprising an iterative module, the iterative module comprising:
a transmitted signal extractor operable to generate an extracted transmitted signal based on an initial channel estimate, a received signal, and a data integrity checking method;
a channel estimator operable to generate a subsequent channel estimate based on the received signal and the extracted transmitted signal; and
a subsequent loop initiator operable to determine whether a subsequent iteration criterion has been met.

17. The wireless receiver of claim 16, the transmitted signal extractor operable to generate the extracted transmitted signal by (i) determining an estimate of a transmitted signal based on the initial channel estimate and the received signal and (ii) generating the extracted transmitted signal based on the estimate of the transmitted signal using the data integrity checking method.

18. The wireless receiver as set forth in claim 16, the subsequent loop initiator further operable to initiate a subsequent loop when the subsequent iteration criterion has been met, the transmitted signal extractor further operable to generate a subsequent extracted transmitted signal based on the subsequent channel estimate, the received signal, and the data integrity checking method in the subsequent loop, and the channel estimator further operable to generate an additional subsequent channel estimate based on the received signal and the subsequent extracted transmitted signal in the subsequent loop.

19. The wireless receiver as set forth in claim 18, further comprising an interference canceller operable to cancel interference in the received signal based on the subsequent channel estimate.

20. The wireless receiver as set forth in claim 16, the subsequent iteration criterion comprising at least one of a predetermined number of iterations having been performed and a difference between consecutive channel estimates that is below a predetermined threshold.
